(19) United States
(12) Patent Application Publication
(10) Pub. No.: US 2024/0016066 A1
(43) Pub. Date: Jan. 11, 2024

(54) MEMORY DEVICE AND METHOD OF FABRICATING THE SAME

(71) Applicant: Taiwan Semiconductor Manufacturing Company, Ltd., Hsinchu (TW)

(72) Inventors: Po-Sheng Lu, Hsinchu City (TW); Zhi-Ren Xiao, Hsinchu County (TW); Nuo Xu, San Jose, CA (US); Zhiqiang Wu, Hsinchu County (TW)

(73) Assignee: Taiwan Semiconductor Manufacturing Company, Ltd., Hsinchu (TW)

(21) Appl. No.: 17/861,234

(22) Filed: Jul. 10, 2022

(51) Int. Cl. H01L 43/04; H01L 27/22; H01L 43/06; H01L 43/14

(52) U.S. Cl. CPC H01L 43/04; H01L 27/228; H01L 43/06; H01L 43/14

(57) ABSTRACT

A memory device includes a substrate, a reference layer, a tunneling layer, a film stack, and a capping layer. The reference layer is disposed on the substrate. The tunneling layer is disposed on the reference layer. The film stack is formed over the tunneling layer and on the substrate, wherein the film stack includes a first free layer, a spacer with high exchange stiffness constant and a second free layer. The first free layer is in contact with the tunneling layer and the film stack. The spacer with high exchange stiffness constant is sandwiched between the first free layer and the second free layer. The capping layer is disposed on and electrically connected to the film stack.

### BACKGROUND

Magnetic random-access memory (MRAM) is a type of memory that uses electron spin to store information (an MRAM device is a spintronics device). MRAM has the potential to become a universal memory able to combine the densities of storage memory with the speed of volatile static random-access memory (SRAM), all the while being non-volatile and power efficient, therefore becoming one of the leading candidates for next-generation memory technologies that aim to surpass the performance of various existing memories. MRAM combines a magnetic device with standard silicon-based microelectronics to obtain the combined attributes of nonvolatility, high-speed operation and unlimited read and write endurance not found in any other existing memory technology. MRAM offers comparable performance to SRAM and comparable density with lower power consumption to volatile dynamic random-access memory (DRAM). As compared to non-volatile flash memory, MRAM offers much faster access speed and suffers minimal degradation over time.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic perspective view illustrating a read and write path of a memory device according to some embodiments of the present disclosure.

FIG. 2 is a schematic cross-sectional view of a semiconductor die including embedded MRAM cells, in accordance with some embodiments.

FIG. 3A to FIG. 3H are schematic cross-sectional views for illustrating a fabricating process in various stages of the semiconductor die illustrated in FIG. 2, in accordance with some exemplary embodiments of the present disclosure.

FIG. 4 is a schematic sectional view of a memory device and a selector over the MRAM cell according to some other embodiments of the present disclosure.

FIG. 5 is a schematic cross-sectional view of a structure of MRAM cell, in accordance with some embodiments.

FIG. 6 is a schematic cross-sectional view of another structure of MRAM cell, in accordance with some embodiments.

FIG. 7A to FIG. 7E are schematic cross-sectional views for illustrating a fabricating process in various stages of the MRAM cell illustrated in FIG. 4, in accordance with some exemplary embodiments of the present disclosure.

FIG. 8A and FIG. 8B are schematic cross-sectional view of different stacked MRAM cell structures, in accordance with some embodiments.

FIG. 9A through FIG. 9E are schematic cross-sectional views for illustrating a fabricating process in various stages of the MRAM cell illustrated in FIG. 4, in accordance with some exemplary embodiments of the present disclosure.

FIG. 10 is a schematic cross-sectional view of a stacked MRAM cell structure, in accordance with some embodiments.

FIG. 11A through FIG. 11E are another schematic cross-sectional view for illustrating a fabricating process in various stages of the MRAM cell illustrated in FIG. 4, in accordance with some exemplary embodiments of the present disclosure.

FIG. 12A and FIG. 12B are schematic cross-sectional view of different stacked MRAM cell structures, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description.

Magneto-resistive random-access memory (MRAM) offers comparable performance to volatile static random-access memory (SRAM) and comparable density with lower power consumption to volatile dynamic random-access memory (DRAM). In addition, the fabrication processes of MRAM are compatible with the existing complementary metal-oxide-semiconductor (CMOS) process. MRAM is a promising candidate for next generation embedded memory devices. One type of an MRAM is a spin transfer torque magnetic random access memory (STT-MRAM). A STT MRAM utilizes a magnetic tunneling junction (MTJ) written at least in part by a current driven through the MTJ. Another type of an MRAM is a spin orbit torque MRAM (SOT-MRAM), which generally requires a lower switching current than a STT-MRAM.

The embodiments of the present disclosure relate to memory devices, and specifically to a MRAM device with spin Hall electrode and methods of forming the same. Generally, the structures and methods of the present disclosure may be used as memory devices including a spin Hall electrode that is patterned to have varying thicknesses at different regions of respective memory device. A global etching process may be performed to pattern the spin Hall electrode, and the spin Hall electrode that is covered by an overlying MTJ structure and a spacer around the MTJ structure is protected from being etched during the global etching process. Thus, the spin Hall electrode may have thicker portion(s) or the thickest portion (with the largest thickness) at the central portion of the memory device and have thinner portion(s) or the thinnest portion (with the smallest thickness) at the peripheral portion(s) of the memory device. That is, the portion that is covered by the MTJ and the spacer is the thicker portion(s) or the thickest portion of the memory device. The thickness difference(s) of the spin Hall electrode can generate difference(s) in resistance at various portions within the spin Hall electrode, leading to increased current flowing from the periphery of the spin Hall electrode to the center of the spin Hall electrode and then flowing into the MTJ structure.

It is to be understood that the memory devices according to embodiments of the present disclosure may comprise a single discrete memory cell, a one-dimensional array of memory cells, or a two-dimensional array of memory cells. It is also to be understood that a one-dimensional array of memory cells of the present disclosure may be implemented as a periodic one-dimensional array of memory cells, and a two-dimensional array of memory cells of the present disclosure may be implemented as a periodic two-dimensional array of memory cells. In addition, while present disclosure is described using embodiments in which memory cells are located within a specific metal interconnect level, e.g., a first metal interconnect level, embodiments are expressly contemplated herein in which the memory cell may be formed within any of the metal interconnect levels.

Magnetoresistive random access memory (MRAM) cell is a form of data storage element for integrated circuits. In comparison with other devices, MRAM cell uses small amounts of power to read and write data. MRAM also has long data retention times in comparison with other devices. In some embodiments, MRAM cells have multi-year data retention times, while the power consumption for reading and writing data is similar to single read or write operations for dynamic random access memory (DRAM) cells. However, in contrast to DRAM cells, MRAM cells are able to store data without regular refreshing of cells in order to preserve stored data.

MRAM cells include magnetic tunnel junctions (MTJs) that enable the use of tunneling magnetoresistance (TMR) to determine the information state of an MRAM cell. A magnetic tunnel junction includes a stack of at least three layers, including a dielectric tunneling barrier layer and two ferromagnetic layers separated by the dielectric tunneling barrier layer. The two ferromagnetic layers includes a reference layer (also called a magnetic pinned layer) and a free layer 100A (also called a magnetic storage layer). The reference layer has a layer of magnetizable material with a locked magnetic field orientation, and the free layer 100A has a layer of magnetizable material where the magnetic field orientation changes between different orientations.

When the magnetic field of the reference layer and the free layer 100A are aligned having the same orientation, the MRAM cell allows a large amount of current to flow in comparison to the allowed amount of current flowing through the MRAM cell when the magnetic field of the reference layer and the magnetic field of the free layer 100A have opposite orientations. The different amounts of current are associated with different information states (e.g., a high amount of current is associated with a “1” bit, and a low amount of current is associated a “0” bit, or vice versa) of the MRAM cell.

MRAM cells are of increasing interest in integrated circuit and semiconductor manufacturing because the magnetic fields of MRAM cells are able to provide long-term data storage. In some embodiments, the magnetization of the reference layer and/or the free layer 100A of an MTJ in an MRAM cell retain the magnetic field orientations associated with a stored bit of information for up to several years, or longer, before thermally-induced field flipping occurs. The read time and the write time of MRAM cells are fast (on the order of DRAM cell reading speed), but the data retention time is at orders of magnitude longer than data retention time of DRAM cells without refreshing.

A stored bit of information may be written into the free layer 100A by applying charge current passing through an MTJ of an MRAM cell. The applied charge current passing through the reference layer becomes spin polarized and exerts a torque on the free layer 100A. The direction of the applied charge current and magnetization of the reference layer determines the direction of generated torque. A large enough torque can switch the magnetic field of the free layer 100A. When performing a “write” procedure of the MRAM cell, a bidirectional charge current is required to determine the information state (i.e., magnetic field) of the free layer 100A such that a “0” bit or a “1” bit may be stored in the MTJ of the MRAM cell.

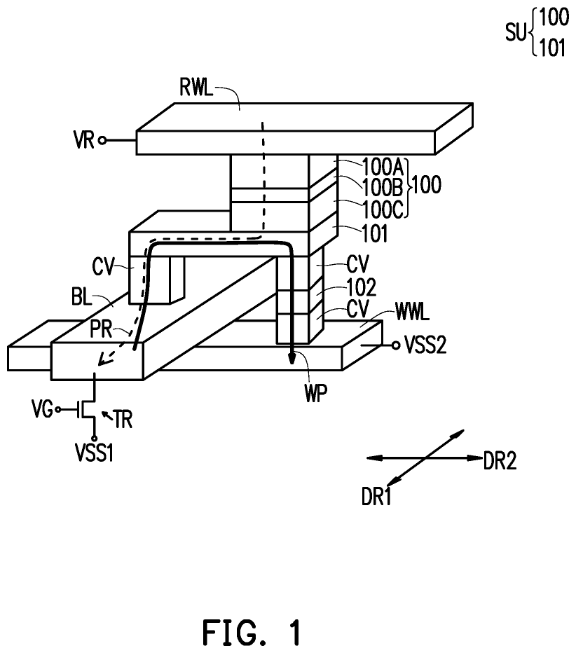

FIG. 1 is a schematic perspective view illustrating a read and write path of a memory device according to some embodiments of the present disclosure.

Referring to FIG. 1, the memory device is a magnetoresistive random-access memory (MRAM) device. In some embodiments, the memory device is embedded in an interconnection structure (not shown) formed over logic devices (not shown, such as active devices, passive devices or a combination thereof). At least a portion of the logic devices may be configured to control the memory device. The memory device includes a magnetic tunnel junction (MTJ) 100. The MTJ 100 may include an insulating layer 100B (or referred as a tunnel barrier, or referred as a spacer) sandwiched between ferromagnetic layers including a pinned layer 100C and a free layer 100A. Magnetization direction of the free layer 100A can be switched by an external magnetic field, whereas magnetization direction of the pinned layer 100C is fixed. If the magnetizations of the free layer 100A and the pinned layer 100C are in a parallel orientation, it is more likely that electrons will tunnel through the insulating layer than if the magnetizations are in oppositional (antiparallel) orientation. Consequently, the MTJ 100 can be switched between a high resistance state and a low resistance state. In this way, the MTJ 100 can be functioned as a storage unit SU.

In some embodiments, the memory device is a spin-orbit torque MRAM (SOT-MRAM) device. In these embodiments, a magnetoresistive storage unit SU of the memory device not only includes the MTJ 100, but also includes a spin-orbit torque (SOT) layer 101, which may be made of a heavy metal (e.g., W, Pt, Ta, Ru, Co, Fe, Cu, the like or combinations thereof), a topological insulator (e.g., Bi₂Se₃, MgO etc.) or other suitable materials. The SOT layer 101 may be formed as a conductive patch, and the MTJ 100 is standing on the SOT layer 101. During a read operation, read current passes (indicated as the read path RP shown in FIG. 1) through the MTJ 100. On the other hand, during a write operation, SOT induces switching of the free layer 100A of the MTJ 100 by injecting an in-plane current in the SOT layer 101 (indicated as the write path WP shown in FIG. 1). As a result of such separate read path RP and write paths WP, the magnetoresistive storage unit SU may have three terminals. In some embodiments, the three terminals are electrically coupled to a read word line RWL, a bit line BL and a write word line WWL, respectively. The read path RP (as shown in FIG. 1) is established between the read word line RWL and the bit line BL, and the write path WP (as shown in FIG. 1) is established between the write word line WL and the bit line BL. Regarding configuration of these transmission lines, the read word line RWL is electrically connected to the MTJ 100, whereas the bit line BL and the write word line WWL are electrically connected to the SOT layer 101.

A conductive via CV may be disposed between the read word line RWL and the MTJ 100. In addition, a conductive via CV may be disposed between the bit line BL and the SOT layer 101, and at least one conductive via CV may be disposed between the write word line WWL and the SOT layer 101. The conductive via CV electrically connected to the bit line BL may be laterally separated from the conductive via(s) CV electrically connected to the write word line WWL, and the MTJ 100 is standing on a portion of the SOT layer 101 located between theses separated conductive vias CV. For instance, the SOT layer 101 is formed as a rectangular conductive patch, and these separated conductive visas CV may be connected to diagonal corners of the SOT layer 101, respectively. In some embodiments, the MTJ 100 and the read word line RWL are located at a top side of the SOT layer 101, whereas the bit line BL and the write word line WWL may be located at a bottom side of the SOT layer 101. In addition, the bit line BL may extend along a direction intersected with a direction along which the read word line RWL and the write word line WWL extend. For instance, the bit line BL may extend along a first direction DR1, whereas the read word line RWL and the write word line WWL may extend along a second direction DR2 substantially perpendicular to the first direction DR1.

In some embodiments, the memory device further includes a selector 102. The selector 102 is connected between the SOT layer 101 and the write word line WWL, and may be functioned as a switch on the write path WP (shown in FIG. 1). The selector 102 may be a two-terminal selector. When a bias voltage across the selector 102 (i.e., a voltage difference between the bit line BL and the write word line WWL) is greater than a turn-on voltage of the selector 102, the selector 102 becomes conductive, and the write path WP (shown in FIG. 1) can be established. In contrast, when the bias voltage across the selector 102 does not reach to the turn-on voltage of the selector 102, the selector 102 is insulative, and the write path WP (shown in FIG. 1) is cut off. As such, the write word line WWL can be selectively in electrical contact with the SOT layer 101.

As compared to a memory device of which a SOT layer 101 is in direct electrical connection to a write word line WWL without a selector in between, the MTJ 100 in the memory device having the selector 102 connected between the SOT layer 101 and the write word line WWL can be avoided from being accidentally programmed when the memory device is not selected by keeping the selector 102 in an off state. In other words, write disturbance of a memory array including a plurality of the memory devices 10 can be reduced. Furthermore, the selector 102 can further prevent the MTJ 100 from being accidentally programmed during a read operation.

In some embodiments, a terminal (e.g., a top terminal) of the selector 102 is connected to the SOT layer 101 through one of the conductive vias CV, and another terminal (e.g., a bottom terminal) of the selector 102 is connected to the write word line WWL through another one of the conductive vias CV. In those embodiments where the bit line BL and the write word line WWL are disposed below the SOT layer 101, bottom ends of the selector 102 and the bit line BL may be at the same height, and the bit line BL and the selector 102 may or may not have the same thickness.

On the other hand, the memory device may not have a selector on the read path RP (shown in FIG. 1). That is, a selector may be absent between the MTJ 100 and the read word line RWL. If a selector is disposed on the read path RP (e.g., between the MTJ 100 and the read word line RWL), a read margin (i.e., a difference between currents flowing through MTJ in different resistance states and collected by the bit line) of the memory device may be compromised as a result of a considerable on-resistance of this selector.

In addition, a method for forming the selector 102 and the overlying and underlying conductive vias CV may include simultaneously patterning material layers (not shown) for forming the selector 102 and conductive layers (not shown) for forming the conductive vias CV, and a lithography process and one or more etching processes may be performed during this patterning step. In this way, sidewalls of the selector 102 and the overlying and underlying conductive vias CV may be coplanar with one another. In addition, the selector 102 and the overlying and underlying conductive vias CV may be collectively regarded as a structure connecting to the write word line WWL, and this structure may or may not be tapered downwardly. In alternative embodiments, the material layers for forming the MTJ 100 and the conductive layer for forming the conductive via CV over the MTJ 100 may be patterned separately. In these alternative embodiments, a sidewall of the MTJ 100 may or may not be coplanar with a sidewall of the overlying conductive via CV. Similarly, the material layers for forming the selector 102 and the conductive layers for forming the conductive vias CV lying below and above the selector 102 may be patterned separately, and sidewalls of the selector 102 and the underlying and overlying conductive vias CV may or may not be coplanar with one another.

In some embodiments, when the memory device is selected during a write operation, the read word line RWL is configured to receive a voltage that can ensure that current will not pass from the SOT layer 102 to the read word line RWL through the MTJ 100. Therefore, formation of sneak current (i.e., current from the SOT layer 102 to the read word line RWL) during a write operation can be suppressed. In these embodiments, the voltage of the read word line RWL during a write operation is substantially equal to or greater than a voltage level of the SOT layer 102. As an illustration shown in FIG. 1, the voltage level at the SOT layer 102 and the voltage received by the read word line RWL during a write operation may both be substantially equal to half of the write voltage VP.

In some embodiments, the memory device includes a plurality of bit lines, a plurality of word lines, a plurality of Spin Hall Effect (SHE) lines, a plurality of selectors, and a plurality of SHE-assisted MRAM cells arranged in array. The bit lines may include bit line BL(1), bit line BL(2), . . . , and bit line BL(m) (not shown). The bit line BL(1) and the bit line BL(2) are not illustrated in FIG. 1 for simplicity. The number of the bit lines may be modified based on design requirements (e.g., memory capacity, process capability, and so on) of the memory device and not limited in the present invention. In some embodiments, the bit line BL(1), the bit line BL(2), . . . , the bit line BL(m) are substantially paralleled with one another. In some embodiments, each bit line among the bit line BL(1), the bit line BL(2), . . . , and the bit line BL(m) is electrically coupled to a relative high voltage level (e.g., VDD) through a group of transistors, which are composed of transistor TR, coupled in parallel. The voltage level (e.g., VDD) applied to and current flowing through the bit line BL(1), the bit line BL(2), . . . , and the bit line BL(m) may be individually controlled by respective groups of transistors which are electrically coupled to the bit line BL(1), the bit line BL(2), . . . , and the bit line BL(m). Each group of transistors electrically coupled to the bit line BL(1), the bit line BL(2), . . . , and the bit line BL(m) may be individually turned on by applying a gate voltage VG to gates of each group of transistors.

The word lines may include read word line RWL(1), read word line RWL(2), . . . , read word line RWL(n) (not shown). The read word line RWL(1) and the read word line RWL(2) are not illustrated in FIG. 1 for simplicity. The number of the word lines may be modified based on design requirements (e.g., memory capacity, process capability, and so on) of the memory device and not limited in the present invention. In some embodiments, the read word line RWL(1), the read word line RWL(2), . . . , and the read word line RWL(n) are substantially paralleled with one another. Furthermore, the extending direction of the bit line BL(1), the bit line BL(2), . . . , and the bit line BL(m) may be substantially perpendicular to the extending direction of the read word line RWL(1), the read word line RWL(2), . . . , and the read word line RWL(n).

In some embodiments, each bit line among the write word line WWL(1), the write word line WWL(2), . . . , and the write word line WWL(n) is electrically coupled to a relative low voltage level VSS (e.g., ground) through a group of transistors coupled in parallel. The voltage level VSS applied to and current flowing through the write word line WWL(1), the write word line WWL(2), . . . , and the write word line WWL(n) may be individually controlled by respective groups of transistors which are electrically coupled to the write word line WWL(1), the write word line WWL(2), . . . , and write word line WWL(n). Each group of transistors electrically coupled to the write word line WWL(1), the write word line WWL(2), . . . , and the write word line WWL(n) may be individually turned on by applying a gate voltage VG to gates of each group of transistors.

The auxiliary lines may include auxiliary line SHEL(1), auxiliary line SHEL(2), . . . , and auxiliary line SHEL(n). The auxiliary line SHEL(1) and the auxiliary line SHEL(2) are not illustrated in FIG. 1 for simplicity. The number of the auxiliary lines may be modified based on design requirements (e.g., memory capacity, process capability, and so on) of the memory device and not limited in the present invention. In some embodiments, the auxiliary line SHEL(1), the auxiliary line SHEL(2), . . . , and the auxiliary line SHEL(n) are substantially paralleled with one another. In some embodiments, the extending direction of the word line WL(1) (including the read word line RWL(1) and the write word line WWL(1)), the word line WL(2), . . . , and the word line WL(n) (including the read word line RWL(n) and the write word line WWL(n)) are substantially paralleled with the extending direction of the auxiliary line SHEL(1), the auxiliary line SHEL(2), . . . , and the auxiliary line SHEL(n). Furthermore, the extending direction of the auxiliary line SHEL(1), the auxiliary line SHEL(2), . . . , and the auxiliary line SHEL(n) may be substantially perpendicular to the extending direction of the bit line BL(1), the bit line BL(2), . . . , and the bit line BL(m) (not illustrated in FIG. 1).

The selectors 102 may include selector S(1, 1), . . . , and selector S(m, n). Only the selector 102 is illustrated in FIG. 1 for simplicity. The number of the selectors may be determined by the numbers of the bit lines, words lines, and/or auxiliary lines, which may be modified based on design requirements (e.g., memory capacity, process capability, and so on) of the memory device. The number of the selectors is not limited in the present invention. Although not illustrated in FIG. 1, the selector S (1, 1) is a selector disposed between the bit line BL(1) and the write word line WWL(1). For example, the selector S(m, n) is a selector disposed between the bit line BL(m) and the word line WWL(n). In some embodiments, the selector S(m, n) is a diode and may be turned on by a forward bias. The selector S(m, n) may be indium zinc oxide (IZO) diode disposed between and electrically coupled to the bit line BL(m) and the write word line WWL(n). The selector S(m, n) may be selected and turned on by a forward bias (e.g., a difference between the gate voltage VG of the transistor TR and the voltage level of the reference voltage VSS2) applied by the bit line BL(m) and the write word line WWL(n).

In some embodiments, the MRAM may include SHE-assisted MRAM cells arranged in an array. The SHE-assisted MRAM cell is not illustrated in FIG. 1 for simplicity. The number of the SHE-assisted MRAM cells may be determined by the numbers of the bit lines, words lines, and/or auxiliary lines, which may be modified based on design requirements (e.g., memory capacity, process capability, and so on) of the memory device. The number of the SHE-assisted MRAM cells is not limited in the present invention. Although not illustrated in FIG. 1, the SHE-assisted MRAM cell is a cell disposed between the bit line BL and the read word line RWL, and the SHE-assisted MRAM cell is also disposed between the read word line RWL and the write word line WWL. The above-mentioned “m” and “n” are positive integers, wherein the integer m is greater than 2, and the integer n is greater than 2.

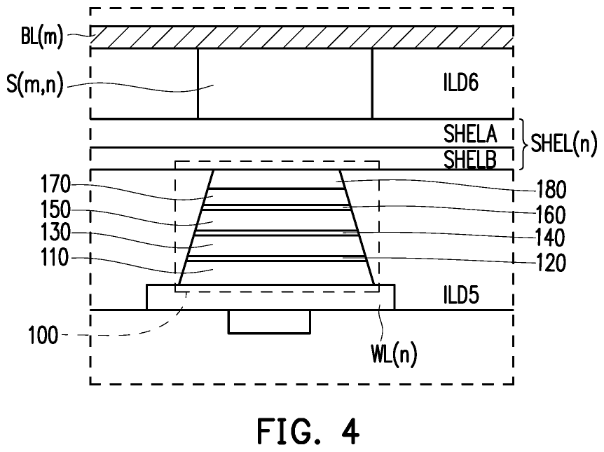

In some other embodiments, each of the SHE-assisted MRAM cell includes a perpendicular MTJ. The MTJ included in each SHE-assisted MRAM cell may respectively include a reference layer (or a pinned layer) 100C, a free layer 100A disposed over the reference layer 100C and a dielectric spacer (or a dielectric tunneling barrier layer) 100B disposed between the free layer 100A and the reference layer 100C, wherein the reference layer 100C has a layer of magnetizable material with a locked magnetic field orientation, and the free layer 100A has a layer of magnetizable material (may be CoFeB, FeB, etc.) where the magnetic field orientation changes between different orientations. In some other embodiments, the MTJ included in each SHE-assisted MRAM cell may further include other functional layers such as seed layer, anti-pinning layer, spacer layer, and/or keeper. The detailed description of the structure of the MTJ included in each SHE-assisted MRAM cell will be described in accompany with FIG. 4.

As illustrated in FIG. 1, the word line WL may be fabricated by a first patterned conductive wiring layer in an interconnect structure of a semiconductor die. The auxiliary line (not shown) may be fabricated by a second patterned conductive wiring layer in the interconnect structure of the semiconductor die. The bit line BL may be fabricated by a third patterned conductive wiring layer in the interconnect structure of the semiconductor die. The third patterned conductive wiring layer is disposed above and the second patterned conductive wiring layer, and the second patterned conductive wiring layer is disposed above the first patterned conductive wiring layer. In other words, the second patterned conductive wiring layer is formed between the first patterned conductive wiring layer and the third patterned conductive wiring layer. Furthermore, the first patterned conductive wiring layer is spaced apart from the second patterned conductive wiring layer by a first dielectric layer (not illustrated in FIG. 1), and the second patterned conductive wiring layer is spaced apart from the third patterned conductive wiring layer by a second dielectric layer (not illustrated in FIG. 1). The SHE-assisted MRAM cell may be formed in the first dielectric layer between the first patterned conductive wiring layer and the second patterned conductive wiring layer, and the selector 102 in the second dielectric layer between the second patterned conductive wiring layer and the third patterned conductive wiring layer.

As shown in FIG. 1, when the memory device is selected during a read operation, the read word line RWL and the bit line BL are configured to receive a read voltage VR and a reference voltage VSS1 (e.g. a ground voltage) of a transistor TR, respectively. The transistor TR is controlled by a gate voltage VG. In this way, a bias voltage across the MTJ 100 (i.e., a difference between the read voltage VR and the reference voltage VSS) results in current passing through the MTJ 100 along the read path RP. This current may be detected by a sense amplifier (not shown), and a resistance state of the MTJ 100 can be detected. In other words, data stored in the MTJ 100 can be read.

In some embodiments, when the memory device is selected during a read operation, the write word line WWL is configured to receive a voltage that can ensure that a voltage difference between the bit line BL and the write word line WWL will not switch on the selector 102. In this way, the write path WP as shown in FIG. 1 would not be formed during a read operation, and the MTJ 100 can be avoided from being accidentally programmed during a read operation. For instance, the voltage of the write word line WWL during a read operation may be substantially equal to or less than half of the read voltage VR (i.e., VR/2), and greater than or substantially equal to the reference voltage VSS1. As an illustration shown in FIG. 1, the voltage of the write word line WWL during a read operation is half of the read voltage VR.

In a read procedure, a sensing current flows in the SHE-assisted MRAM cell. When magnetizations of reference layer 100C and free layer 100A are parallel to each other in the SHE-assisted MRAM cell, the resistance of the SHE-assisted MRAM cell reaches a minimum value, thereby the sense current reading a “0” code. When both magnetizations are antiparallel to each other in the SHE-assisted MRAM cell, the resistance of the SHE-assisted MRAM cell reaches a maximum value, thereby the sense current reading a “1” code.

As shown in FIG. 1, when the memory device is selected during a write operation, the write word line WWL and the bit line BL are configured to receive a write voltage VP and the reference voltage VSS1, respectively. The write voltage VP is large enough that a voltage difference between the write voltage VP and the reference voltage VSS1 is greater than a turn-on voltage of the selector 102. In this way, the selector 102 can be switched on, and current path can be established between the write word line WWL and the bit line BL (i.e., the write path WP). Once the write path WP is established, an in-plane current passes through the SOT layer 102, and consequently formed SOT induces switching of the free layer (not shown) in the MTJ 100. As such, the MTJ 100 can be programmed.

When a Spin transfer torque (STT) write procedure of the SHE-assisted MRAM cells is performed, the transistor TR electrically coupled to the bit line BL is turned on. The selector 102 is selected and turned on because the transistors TR electrically coupled to the bit line BL and the write word line WWL are turned on. A stored bit of information may be written into the free layer 100A by applying the STT write current passing through the MTJ along the write path WP in the SHE-assisted MRAM cell. The applied the STT write current passing through the reference layer 100A of the MTJ 100 becomes spin polarized and exerts a torque on the free layer. The direction of the STT write current and magnetization of the reference layer determines the direction of generated torque. The write current transmitted by the auxiliary line may create write ability of the SHE-assisted MRAM cell. Furthermore, since the word line WL and the bit lines BL are coupled to groups of transistors, the STT write current and the read current utilized in the operation of (i.e. read and write procedures) of the SHE-assisted MRAM cells may increases so as to improve the operation stability of the SHE-assisted MRAM cells.

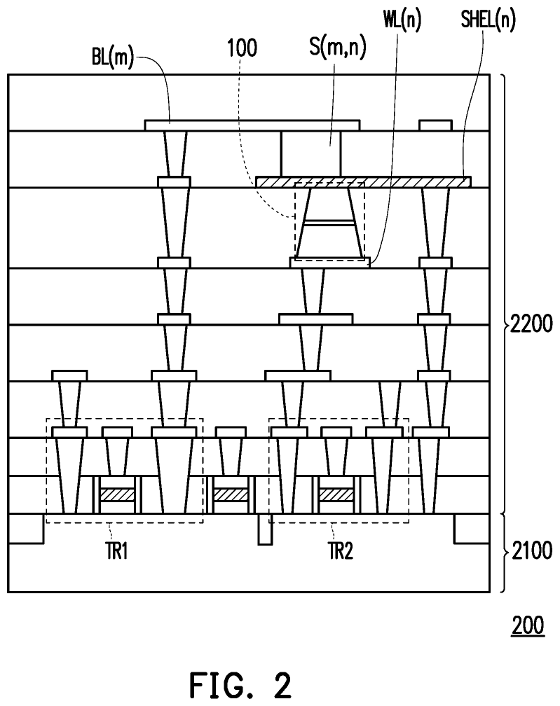

FIG. 2 is a schematic cross-sectional view of a semiconductor die including embedded MRAM cells, in accordance with some embodiments.

Referring to FIG. 1 and FIG. 2, semiconductor die 200 may include a semiconductor substrate 2100 including a plurality of transistors TR1 and a plurality of transistors TR2 formed thereon and an interconnect structure 2200 over the semiconductor substrate 2100. One transistor TR1 and one transistor TR2 are illustrated in FIG. 2 for simplicity. The transistors TR1 and TR2 formed over the semiconductor substrate 2100 may be FinFETs, MOSFETs, GAA nanowire FETs, GAA nanosheet FETs or the like. The interconnect structure 2200 may include a plurality of dielectric layers and a plurality of interconnect wirings (e.g., copper wirings). To integrate the memory device illustrated in FIG. 1 into the semiconductor die 200, the bit lines, the word lines WL(n), the auxiliary lines SHEL(n), the selectors S(m, n), and the SHE-assisted embedded MRAM cells (including MTJ 100) are embedded in the interconnect structure 2200. In other words, the formation of the bit lines, the word lines, the auxiliary lines, the selectors, and the SHE-assisted embedded MRAM cells may be integrated in the fabrication of the interconnect structure 2200 of the semiconductor die 200.

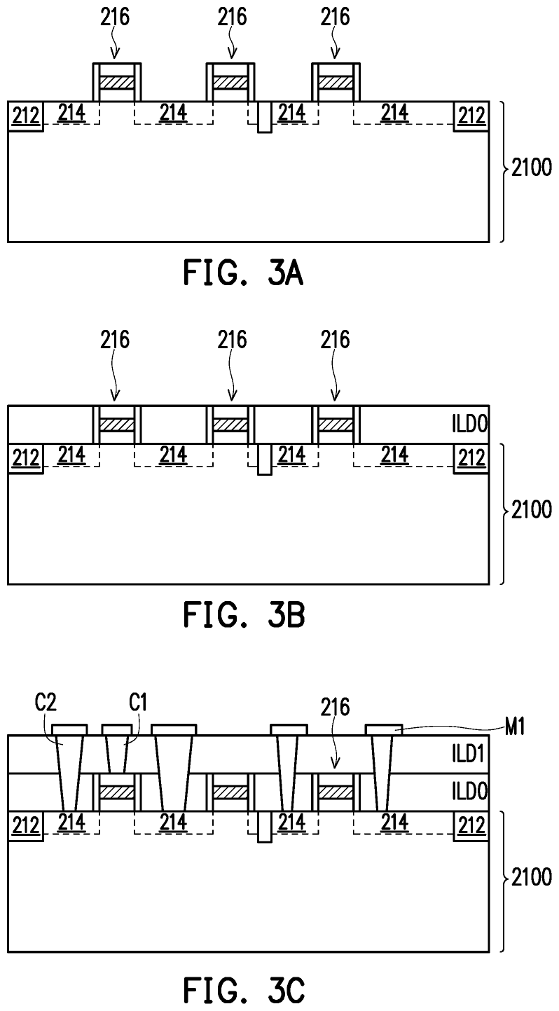

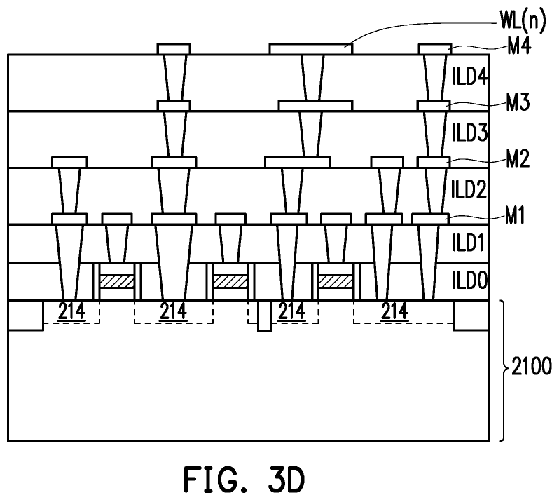

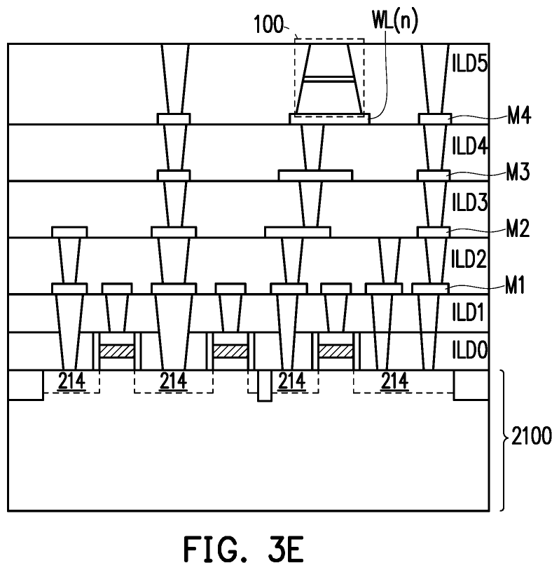

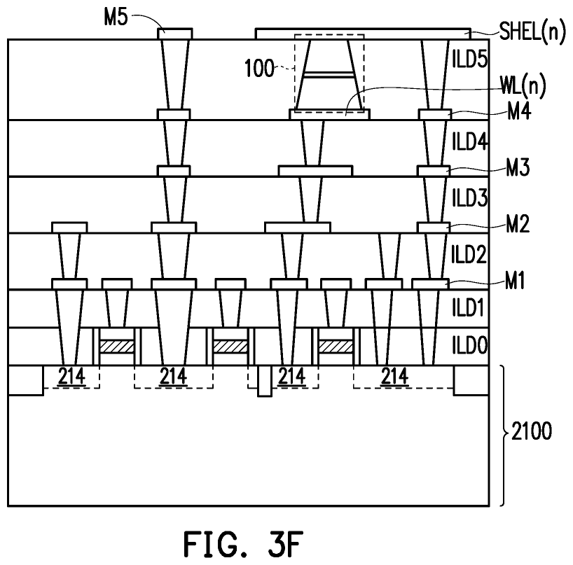

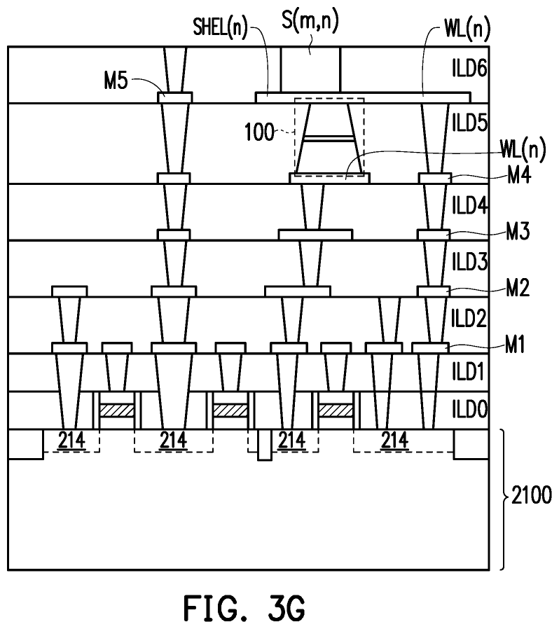

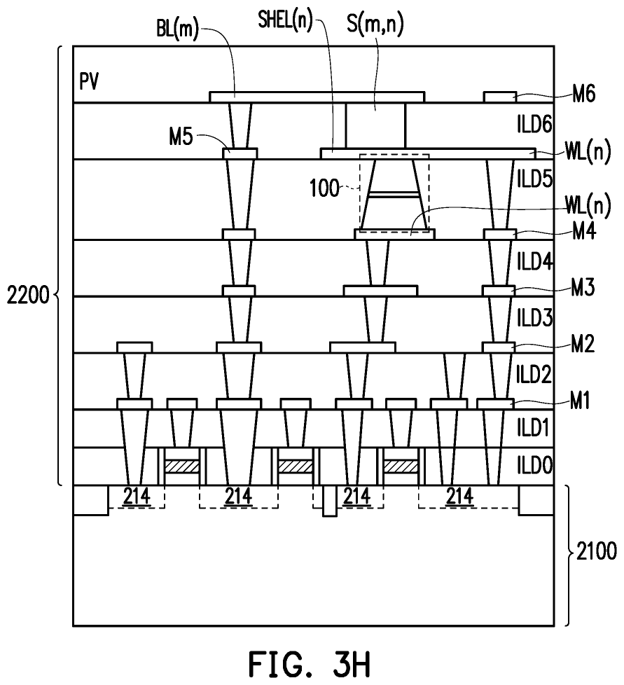

As illustrated in FIG. 2, when the STT write procedure of the SHE-assisted MRAM cell is performed, gate voltage is applied to the gate electrodes of the transistors TR1 and gate voltage is applied to the gate electrodes of the transistors TR2 to turned on the transistors TR1 and TR2 such that the STT write current from a source line may sequentially flow through channel of the transistor TR1, interconnect wirings in the interconnect structure 2200, the bit line BL(m), the selector S(m, n), the SHE-assisted embedded MRAM cells, the word line WL(n), and the channel of the transistor TR2. During the STT write procedure of the SHE-assisted MRAM cell, by the assistance of the SHE-assisted current, a bit of information is stored in the SHE-assisted MRAM cell through STT write mechanism. The detailed fabrication process will be described in accompany with FIG. 3A through FIG. 3H. The memory device further includes an auxiliary line SHEL(n) and a selector S(m, n). The auxiliary line is disposed on the capping layer. The selector S(m, n) is disposed on the auxiliary line SHEL(n) and electrically connected to the BL(m) bit line and the film stack, wherein the selector S(m, n) is one of threshold-type selector and exponential type selector.

Referring to FIGS. 1 and 2, the threshold-type selector is a conductive bridge (CB) selector, which may also be referred as a voltage conductive bridge (VCB) selector. In these embodiments, the SOT layer 101 as shown in FIG. 1 is replaced by a tunneling layer. Given a fixed thickness of the tunneling layer, carriers may tunnel through the tunneling layer by controlling a bias voltage of the tunneling layer. This tunneling behavior can be explained by, for example, direct tunneling effect or Fowler-Nordheim tunneling (FN tunneling) effect. Once the tunneling of carriers is formed between the conductive layers, the selector 102 is turned on. Otherwise, the selector 102 is in an off state. In some embodiments, a material of the tunneling layer may include titanium oxide, tantalum oxide, nickel oxide or the like. In certain embodiments, the tunneling layer is a multilayer structure including, for example, a TiN layer and a Si layer.

FIG. 3A to FIG. 3H are schematic cross-sectional views for illustrating a fabricating process in various stages of the semiconductor die illustrated in FIG. 2, in accordance with some exemplary embodiments of the present disclosure.

Referring to FIG. 3A, a semiconductor substrate 2100 including doped source/drain regions. In some embodiments, the semiconductor substrate 2100 is a bulk semiconductor substrate. A “bulk” semiconductor substrate refers to a substrate that is entirely composed of at least one semiconductor material. In some embodiments, the bulk semiconductor substrate includes a semiconductor material or a stack of semiconductor materials such as, for example, silicon (Si), germanium (Ge), silicon germanium (SiGe), carbon doped silicon (Si:C), silicon germanium carbon (SiGeC); or an III-V compound semiconductor such as, for example, gallium arsenide (GaAs), gallium phosphide (GaP), indium phosphide (InP), indium arsenide (InAs), indium antimonide (InSb), gallium arsenide phosphide (GaAsP), aluminum indium arsenide (AlInAs), aluminum gallium arsenide (AlGaAs), gallium indium arsenide (GaInAs), gallium indium phosphide (GaInP), or gallium indium arsenide phosphide (GaInAsP). In some embodiments, the bulk semiconductor substrate includes a single crystalline semiconductor material such as, for example, single crystalline silicon. In some embodiments, the bulk semiconductor substrate is doped depending on design requirements. In some embodiments, the bulk semiconductor substrate is doped with p-type dopants or n-type dopants. The term “p-type” refers to the addition of impurities to an intrinsic semiconductor that creates deficiencies of valence electrons. Exemplary p-type dopants, i.e., p-type impurities, include, but are not limited to, boron, aluminum, gallium, and indium. “N-type” refers to the addition of impurities that contribute free electrons to an intrinsic semiconductor. Exemplary n-type dopants, i.e., n-type impurities, include, but are not limited to, antimony, arsenic, and phosphorous. If doped, the semiconductor substrate 2100, in some embodiments, has a dopant concentration in a range from 1.0×10¹⁴ atoms/cm³ to 1.0×10⁷ atoms/cm³, although the dopant concentrations may be greater or smaller. In some embodiments, the semiconductor substrate 2100 is a semiconductor-on-insulator (SOI) substrate including a top semiconductor layer formed on an insulator layer (not shown). The top semiconductor layer includes the above-mentioned semiconductor material such as, for example, Si, Ge, SiGe, Si:C, SiGeC; or an III-V compound semiconductor including GaAs, GaP, InP, InAs, InSb, GaAsP, AlInAs, AlGaAs, GaInAs, GaInP, or GaInASP. The insulator layer is, for example, a silicon oxide layer, or the like. The insulator layer is provided over a base substrate, typically a silicon or glass substrate.

A plurality of isolation structures 212 may be formed in the semiconductor substrate 2100 to define an active area where transistors (TR1 and TR2) illustrated in FIG. 2 are formed. In some embodiments, source/drain regions 214 and gate structures 216 of the transistors (TR1 and TR2) may be formed over the semiconductor substrate 2100.

Referring to FIG. 3B, after forming the source/drain regions 214 and gate structures 216 of the transistors (TR1 and TR2), an interlayer dielectric layer ILD0 is formed over the semiconductor substrate 2100. In some embodiments, the interlayer dielectric layer ILD0 includes silicon oxide. Alternatively, in some embodiments, the interlayer dielectric layer ILD0 includes a low-k dielectric material having a dielectric constant (k) less than 4. In some embodiments, the low-k dielectric material has a dielectric constant from about 1.2 to about 3.5. In some embodiments, the interlayer dielectric layer ILD0 includes tetraethylorthosilicate (TEOS) formed oxide, undoped silicate glass, or doped silicate glass such as borophosphosilicate glass (BPSG), fluorosilica glass (FSG), phosphosilicate glass (PSG), boron doped silicon glass (BSG), and/or other suitable dielectric materials. In some embodiments, the interlayer dielectric layer ILD0 is deposited by CVD, PECVD, PVD, or spin coating. In some embodiments, the interlayer dielectric layer ILD0 is deposited to have a top surface above the top surface of the gate structures 216. The interlayer dielectric layer ILD0 is subsequently planarized, for example, by CMP and/or a recess etch using the gate structures 216 as a polishing and/or etch stop. After the planarization, the interlayer dielectric layer ILD0 has a surface substantially coplanar with the top surface of the gate structures 216.

Referring to FIG. 3C, after forming the interlayer dielectric layer ILD0, an interlayer dielectric layer ILD1 is formed to cover the interlayer dielectric layer ILD0. In some embodiments, the interlayer dielectric layer ILD1 includes silicon oxide. Alternatively, in some embodiments, the interlayer dielectric layer ILD1 includes a low-k dielectric material having a dielectric constant (k) less than 4. In some embodiments, the low-k dielectric material has a dielectric constant from about 1.2 to about 3.5. In some embodiments, the interlayer dielectric layer ILD1 includes TEOS formed oxide, undoped silicate glass, or doped silicate glass such as BPSG, FSG, PSG, BSG, and/or other suitable dielectric materials. In some embodiments, the interlayer dielectric layer ILD1 is deposited by CVD, PECVD, PVD, or spin coating. In some embodiments, the interlayer dielectric layer ILD1 is deposited to have a top surface. The interlayer dielectric layer ILD0 and the interlayer dielectric layer ILD1 are patterned to formed contact openings for exposing portions of the source/drain regions 214. Then, metallic material is formed to cover the interlayer dielectric layer ILD1 and fill the opening defined in the dielectric layer ILD0 and the interlayer dielectric layer ILD1. The metallic material is subsequently patterned, for example, by photolithography and etch processes such that gate contacts C1, source/drain contacts C2, and interconnect wirings M1 are formed, wherein the interconnect wirings M1 are formed over the interlayer dielectric layer ILD1, the gate contacts C1 are in contact with the gate structure 116, and the source-drain contacts C2 are in contact with the source/drain regions 214.

Referring to FIG. 3D, an interlayer dielectric layer ILD2, interconnect wirings M2, an interlayer dielectric layer ILD3, interconnect wirings M3, an interlayer dielectric layer ILD4, and interconnect wirings M4 are sequentially formed over the interlayer dielectric layer ILD1. The fabrication process of the interlayer dielectric layer ILD2, the interconnect wirings M2, the interlayer dielectric layer ILD3, the interconnect wirings M3, the interlayer dielectric layer ILD4, and the interconnect wirings M4 are similar with the fabrication process of the interlayer dielectric layer ILD1 and the interconnect wirings M1. Detailed description related to the fabrication process is thus omitted.

In some embodiments, after forming the interlayer dielectric layer ILD4 and the interconnect wirings M4, word lines are formed to electrically connect to the source/drain regions 214 of the transistors TR2. For simplicity, only the word line WL(n) is illustrated in FIG. 3D. In some other embodiments, the word lines are formed by more than four interconnect wirings in the interconnect structure. In some alternative embodiments, the word lines are formed by less than four interconnect wirings in the interconnect structure. The number of the interconnect wirings included in the word lines is not limited in the present invention.

Referring to FIG. 3E, SHE-assisted MRAM cells arranged in array may be formed on and in contact with the interconnect wirings M4 such that the SHE-assisted MRAM cells are formed on and in contact with the respective bit lines. For simplicity, only the word line WL(n) is illustrated in FIG. 3E. Take the SHE-assisted MRAM cell as an example, the SHE-assisted MRAM cell is formed on and in contact with the bit line BL(n).

After forming the SHE-assisted MRAM cell (including MTJ 100), an interlayer dielectric layer ILD5 is formed over the interlayer dielectric layer ILD4 to laterally surround the SHE-assisted MRAM cell. The material of the interlayer dielectric layer ILD5 may be similar with that of the interlayer dielectric layer ILD0. In some embodiments, the interlayer dielectric layer ILD5 is deposited by CVD, PECVD, PVD, or spin coating. In some embodiments, the interlayer dielectric layer ILD5 is deposited to have a top surface above the top surface of the SHE-assisted MRAM cell. The interlayer dielectric layer ILD5 is subsequently planarized, for example, by CMP and/or a recess etch using a top portion of the SHE-assisted MRAM cell as a polishing and/or etch stop. After the planarization, the interlayer dielectric layer ILD5 has a surface substantially coplanar with the top surface of the SHE-assisted MRAM cell.

After forming the SHE-assisted MRAM cell and the interlayer dielectric layer ILD5, conductive vias may be formed in the interlayer dielectric layer ILD5 to electrically connects the interconnect wirings M4.

Referring to FIG. 3F, auxiliary lines are formed over the SHE-assisted MRAM cell (including MTJ 100). For simplicity, only the auxiliary line SHEL(n) is illustrated in FIG. 3F. In some embodiments, the material of the auxiliary line SHEL(n) includes anti-ferromagnetic materials such as platinum (Pt), tantalum (Ta), tungsten (W), hafnium (Hf), iridium (Ir), osmium (Os), and manganese (Mn), or alloys thereof. The auxiliary line SHEL(n) may be formed by depositing (e.g., by sputtering or electroplating) the above-mentioned anti-ferromagnetic materials over the interlayer dielectric layer ILD5 followed by a patterning process. The deposited anti-ferromagnetic materials may be subsequently patterned, for example, by photolithography and etch processes to form the auxiliary line SHEL(n).

In some embodiments, interconnect wirings M5 are formed over the interlayer dielectric layer ILD5 after forming the auxiliary line SHEL(n), and the material of the interconnect wirings M5 are identical with or different from that of the auxiliary line SHEL(n). In some other embodiments, interconnect wirings M5 are formed over the interlayer dielectric layer ILD5 before forming the auxiliary line SHEL(n), and the material of the interconnect wirings M5 are identical with or different from that of the auxiliary line SHEL(n). In some alternative embodiments, the auxiliary line SHEL(n) and the interconnect wirings M5 are formed by the same series of processes (e.g., deposition of anti-ferromagnetic materials followed by photolithography and etch processes), and the material of the interconnect wirings M5 are identical with that of the auxiliary line SHEL(n).

Referring to FIG. 3G, selectors are formed over the auxiliary lines. For simplicity, only the selector S(m, n) is illustrated in FIG. 3G. In an embodiment in which the selector S(m, n) is an IZO diode, the IZO diode may be formed by depositing IZO material followed by a patterning process. IZO material may be deposited over the interconnect wirings M5 and the interlayer dielectric layer ILD5, and may be then patterned, for example, by photolithography and etch processes to form the selector S(m, n) over the interconnect wirings M5.

After forming the selector S(m, n), an interlayer dielectric layer ILD6 is formed over the interlayer dielectric layer ILD5 to laterally surround the interconnect wirings M5. The material of the interlayer dielectric layer ILD6 may be similar with that of the interlayer dielectric layer ILD5. In some embodiments, the interlayer dielectric layer ILD6 is deposited by CVD, PECVD, PVD, or spin coating. In some embodiments, the interlayer dielectric layer ILD6 is deposited to have a top surface above the top surface of the selector S(m, n). The interlayer dielectric layer ILD6 is subsequently planarized, for example, by CMP and/or a recess etch using a top portion of the selector S(m, n) as a polishing and/or etch stop. After the planarization, the interlayer dielectric layer ILD6 has a surface substantially coplanar with the top surface of the selector S(m, n).

After forming the selector S(m, n) and the interlayer dielectric layer ILD6, conductive vias may be formed in the interlayer dielectric layer ILD6 to electrically connects the interconnect wirings M5. In some embodiments, the conductive vias are formed in the interlayer dielectric layer ILD6 after forming the selector S(m, n). In some other embodiments, the conductive vias are formed in the interlayer dielectric layer ILD6 before forming the selector S(m, n).

Referring to FIG. 3H, interconnect wirings M6 are formed over the interlayer dielectric layer ILD6, and the material of the interconnect wirings M6 are identical with or different from that of the interconnect wirings M5. After forming the interconnect wirings M6, a passivation layer PV is formed over the interlayer dielectric layer ILD6 to cover the interconnect wirings M6. In some embodiments, the passivation layer PV includes silicon oxide, silicon nitride or the like. The passivation layer PV may be deposited by CVD, PECVD, PVD, or spin coating.

FIG. 4 is a schematic sectional view of a memory device and a selector over the MRAM cell according to some other embodiments of the present disclosure.

Referring to FIG. 4, in some other embodiments, the SHE-assisted SOT-MRAM cell may include a buffer layer 110 over the word line WL(n), a seed layer 120 over the buffer layer 110, a hard-biasing layers 130 over the seed layer 120, an antiparallel coupling (APC) layer 140 over the hard-biasing layer 130, at least one reference layer 150 over the antiparallel coupling (APC) layer 140, a dielectric barrier layer 160 over the at least one reference layer 150, at least one free layer 170 over the dielectric barrier layer 160, and a capping layer 280 over the at least one free layer 170. The buffer layer 110 is located on top of the substrate. The seed layer 120 is located in between the buffer layer 110 and the reference layer 150. The seed layer 120 is located in between the buffer layer 110 and the free layer spacer with high exchange stiffness constant material (e.g., Mg and Ta, but not limited hereto).

The buffer layer 110 may include a titanium nitride (TiNX) film having a thickness of about 8 nm and a tantalum nitride (TaNX) film having a thickness of about 2 nm, wherein the tantalum nitride (TaNX) film is laminated on the titanium nitride (TiNX) film. The seed layer 120 may be a nickel-chromium (Ni—Cr) film having a thickness about 5 nm.

The hard biasing layer 130 may include a bottom cobalt (Co) film having a thickness of about 0.3 nm and a platinum (Pt) film having a thickness of about 0.3 nm, as well as an upper Co film having a thickness of about 0.3 nm, wherein the Pt film is sandwiched between the bottom and upper Co films. The antiparallel coupling layer 240 may be an iridium (Ir) film having a thickness of about 0.5 nm.

The reference layer 150 may include a cobalt (Co) film having a thickness of about 0.6 nm, a molybdenum (Mo) film having a thickness of about 0.3 nm, and an iron-boron (Fe—B) film having a thickness of about 1.0 nm, wherein the Mo film is laminated on the Co film, and the Fe—B film is laminated on the Mo film.

The dielectric barrier layer 160 may be a magnesium oxide (MgO) film having a thickness of about 0.8 nm.

The free layers 170 may include an iron-boron (Fe—B) film having a thickness of about 1.0 nm, a magnesium (Mg) film having a thickness of about 0.4 nm, a bottom cobalt-iron-boron (Co—Fe—B) film having a thickness of about 0.6 nm, a MgO film having a thickness of about 0.6 nm, and an upper Co—Fe—B film having a thickness of about 0.4 nm, wherein the Mg film is laminated on the Fe—B film, the bottom Co—Fe—B film is laminated on the Mg film, the MgO film is laminated on the Co—Fe—B film, and the upper Co—Fe—B film is laminated on the MgO film. The capping layer 280 may be a tungsten (W) film having a thickness of about 2 nm.

In some other embodiments, the SHE-assisted SOT-MRAM cell may only include a reference layer 150 over the word line WL(n), a dielectric barrier layer 160 over the reference layer 150, and a free layer 170 over the dielectric barrier layer 160 such that a magnetic tunnel junction (MTJ) 100 is formed.

The auxiliary line SHEL(n) may include a heavy-metal layer SHELB over the SHE-assisted SOT-MRAM cell and the interlayer dielectric layer ILD5. In some embodiments, the heavy-metal layer SHELB includes platinum (Pt), β-tantalum (Ta), β-tungsten (β-W), hafnium (Hf), iridium (Ir), osmium (Os), or alloys thereof. In some embodiments, materials having large spin orbit coupling strength have high electrical resistivity, ranging from about 150 μΩcm to about 250 μΩcm. Electrical resistivity below 150 μΩcm does not consistently produce sufficient spin-orbit coupling to flip the magnetization of the free layer. Electrical resistivity above 250 μΩcm tends to produce a strong spin-orbit coupling effect, but is associated with larger amounts of heat production and power consumption, reducing the low-power consumption and speed benefits of magnetoresistive random access memory.

The auxiliary line SHEL(n) may further include a top electrode layer SHELA over the heavy-metal layer SHELB.

The selector S(m, n) may be embedded in the interlayer dielectric layer ILD6 and disposed over the auxiliary line SHEL(n). The bit line BL(m) may be disposed over the selector S(m, n) and the interlayer dielectric layer ILD6. Furthermore, the selector S(m, n) is disposed between and electrically coupled to the auxiliary line SHEL(n) and the bit line BL(m) such that the selector S(m, n) may be selected and turned on through a forward voltage bias applied by the auxiliary line SHEL(n) and the bit line BL(m).

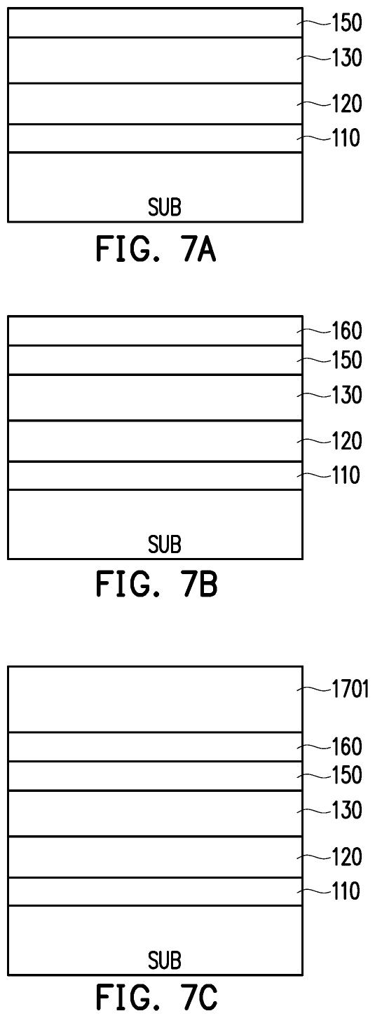

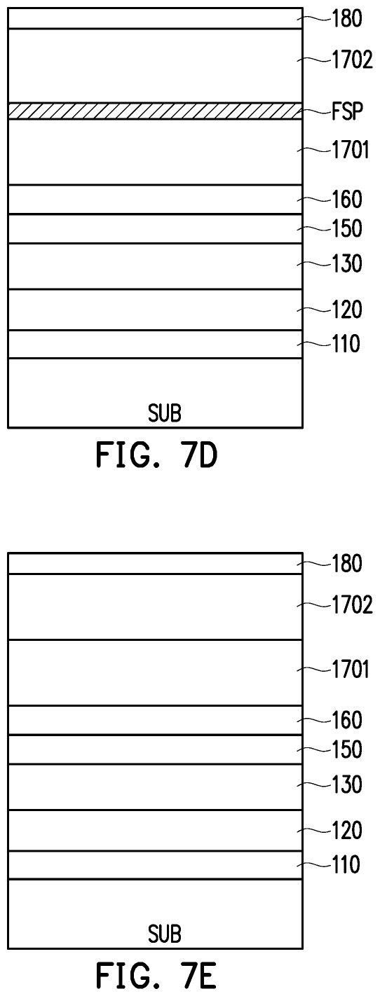

The detailed process of the SHE-assisted SOT-MRAM cell (may only include MTJ 100) are described in accompany with FIG. 7A through FIG. 7E.

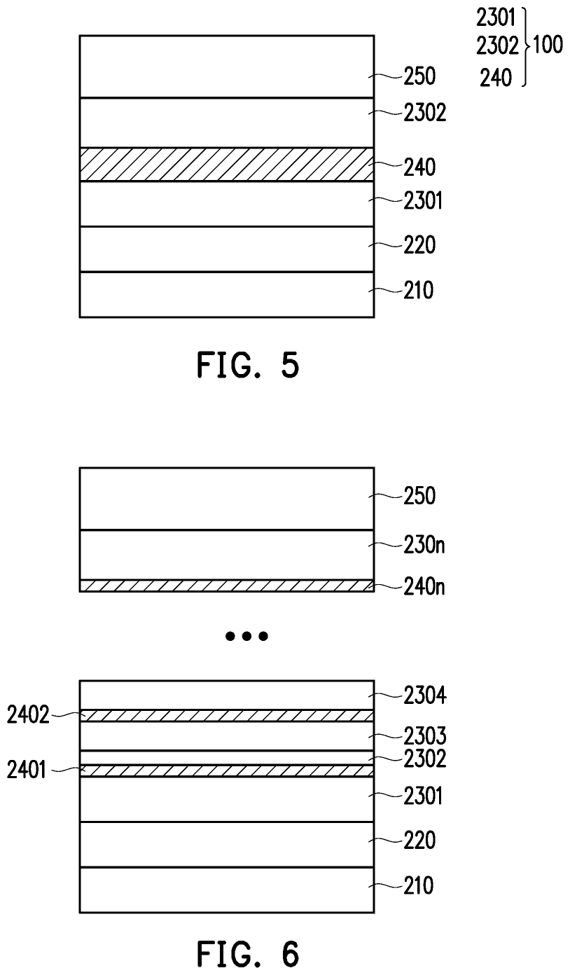

FIG. 5 is a schematic cross-sectional view of a structure of SOT-MRAM cell, in accordance with some embodiments.

Referring to FIG. 5, the SOT-MRAM cell may include a reference layer 210, the tunneling layer 220, the film stack 100, and a capping layer 250. The film stack 100 includes a relatively thin free layer 2301, the free layer spacer 240, and a relatively thin free layer 2302. The reference layer 210 is disposed on a substrate. The tunneling layer 220 is disposed on the reference layer 210. The film stack 100 formed over the tunneling layer 220 and on the substrate. The free layer spacer 240 has high exchange stiffness constant. The relatively thin free layer 2301 is in contact with the tunneling layer 220 and the film stack 100, and the free layer spacer 240 with high exchange stiffness constant is sandwiched between the relatively thin free layer 2301 and the relatively thin free layer 2302. The capping layer 250 is disposed on and electrically connected to the film stack 100. In other words, the capping layer 250 is disposed on and electrically connected to the relatively thin free layer 2302. In some embodiments, the width of the relatively thin free layer 2301 is substantially larger than the width of the relatively thin free layer 2302. In some embodiments, both the relatively thin free layer 2301 and the relatively thin free layer 2302 have a plurality of monolayers.

The free layer spacer 240 with high exchange stiffness constant may include a material comprising metal elements with relatively low atomic weight (or light mass) selected from one of Mg, Al, Si, Ca, Cr, Co, Ta, Fe, and Ni. In some embodiments, the free layer spacer 240 includes Mg and their oxides with predetermined composition. In another embodiments, the free layer spacer 240 includes Ta and their oxides with predetermined composition. In other embodiments, the thickness of the free layer spacer 240 in the film stack 100 is between 0.2 nm to 0.4 nm.

In some embodiments, the thickness of each relatively thin free layers 2301 and 2302 in the film stack 100 is between 0.2 nm to 0.5 nm. In other embodiments, the thickness of each relatively thin free layers 2301 and 2302 in the film stack may thinner than 0.5 nm. In other embodiments, the total thickness of relatively thin free layers 2301, 2302 and the free layer spacer 240 may less or equal to 1 nm. That is, the thickness of the film stack 100 is smaller than or equal to 1 nm. With the relatively thin free layers 2301 and 2302, both high saturation magnetization (Mₛ) and low moment is able to be achieved. As such, the switching current of the MRAM is able to be reduced. In addition, high spin wave stiffness constant (D) is closely and positively related to relatively higher exchange stiffness constant (Aₑₓ) following the formula listed below:

$${A}_{e x} = \frac{D {M}_{s}}{2 g {μ}_{B}}$$

wherein Mₛ is the saturation magnetization, g is the Landé factor (g≈2 for metals) and μ_{B} is the Bohr magneton. The spin wave stiffness constant D is linked to the long wavelength limit of the acoustic mode of magnon dispersion 2. In other words, the thinner the free layer, the larger the spin wave stiffness constant (D), thus lead to higher net exchange stiffness constant (Aₑₓ).

FIG. 6 is a schematic cross-sectional view of another structure of MRAM cell, in accordance with some embodiments.

Referring to FIG. 6, the MRAM cell may include a reference layer 210, the tunneling layer 220, a plurality of the film stacks, and a capping layer 250. The plurality of the magnetic tunneling junction (MTJ) includes a first film stack (i.e., the relatively thin free layer 2301-the free layer spacer 2401-the relatively thin free layer 2301), a second film stack (i.e., the relatively thin free layer 2303-the free layer spacer 2402-the relatively thin free layer 2304), . . . , and the last film stack (i.e., the relatively thin free layer-the free layer spacer 240n-the relatively thin free layer 230n). The multiple-stacked film stack repeats for M periods, wherein M is a positive number and wherein M may be larger than or equal to 2 according to some embodiments. The repeated number M of the repeated structure of the film stacks is predetermined for adjusting the thermal retention factor.

FIG. 7A to FIG. 7E are schematic cross-sectional views for illustrating a fabricating process in various stages of the MRAM cell illustrated in FIG. 4, in accordance with some exemplary embodiments of the present disclosure.

Referring to FIG. 7A to FIG. 7D, the bottom-up process flow for fabricating the MRAM cell is provided. In some exemplary embodiments, the MRAM cell may include a substrate SUB, a buffer layer 110, a seed layer 120, an anti-pinning layer 130, a reference layer 150, a barrier layer 160, relatively thin free layers 1701, 1702, a free layer spacer FSP, and a capping layer 180. In another embodiments, there may be a spacer 140 sandwiched between the anti-pinning layer 130 and the reference layer 150. The relative position is shown in FIG. 7D, those skilled in the art is able to easily known by referring to the embodiments mentioned above, and no more repeated description here.

Referring to FIG. 7A to FIGS. 7C and 7E, the bottom-up process flow for fabricating the MRAM cell is provided. In another exemplary embodiments, the MRAM cell may include a substrate SUB, a buffer layer 110, a seed layer 120, an anti-pinning layer 130, a reference layer 150, a barrier layer 160, relatively thin free layers 1701, 1702, and a capping layer 180. In another embodiments, there may be a spacer 140 sandwiched between the anti-pinning layer 130 and the reference layer 150. The relative position is shown in FIG. 7E, those skilled in the art is able to easily known by referring to the embodiments mentioned above, and no more repeated description here. That is, there is no free layer spacer applied in the fabrication process, and the relatively thin free layers 1701, 1702 forms a free layer pair structure.

Referring to FIG. 7A to 7E, in accordance with another embodiments, the free layer spacer FSP sandwiched between the relatively thin free layers 1701, 1702 is removed. As such, there is no free layer spacer leaved in the film stacks, and the relatively thin free layers 1701, 1702 forms a free layer pair structure.

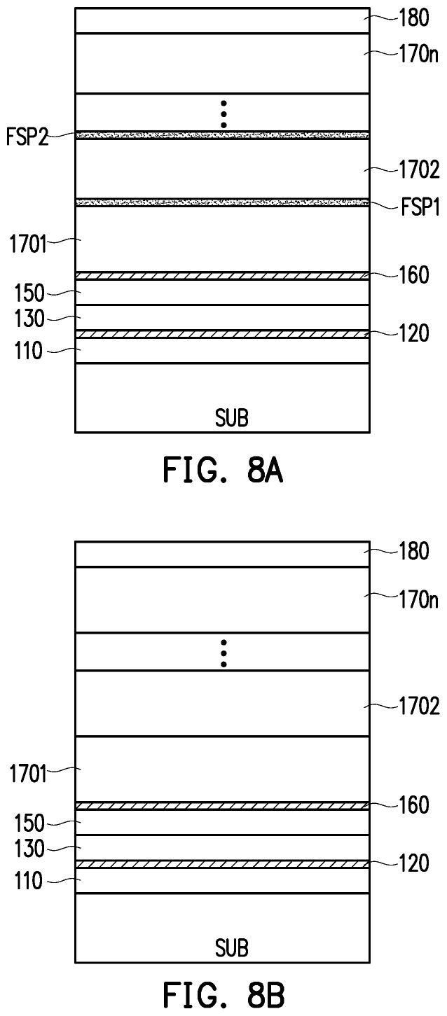

FIG. 8A and FIG. 8B are schematic cross-sectional view of different stacked MRAM cell structures, in accordance with some embodiments.

Referring to FIG. 8A, the MRAM cell with multiple stacked film stack structure is provided according to a bottom-up process flow. In some exemplary embodiments, the MRAM cell may include a substrate SUB, a buffer layer 110, a seed layer 120, an anti-pinning layer 130, a reference layer 150, a barrier layer 160, relatively thin free layers 1701, 1702, . . . , 170n, free layer spacers FSP1, FSP2, . . . , FSPn, and a capping layer 180. In another embodiments, there may be a spacer 140 sandwiched between the anti-pinning layer 130 and the reference layer 150. The relative position is shown in FIG. 8A and no more repeated description here. In some embodiments, the MRAM cell further forms a repeated structure of the film stacks and wherein the thickness of the free layer spacer FSP1, FSP2 is smaller than the thickness of the relatively thin free layer 1701, 1702, . . . , 170n.

Referring to FIG. 8B, the MRAM cell with multiple stacked film stack structure, including free layer pair (e.g., 1701, 1702) is provided according to a bottom-up process flow. In some exemplary embodiments, the MRAM cell may include a substrate SUB, a buffer layer 110, a seed layer 120, an anti-pinning layer 130, a reference layer 150, a barrier layer 160, relatively thin free layers 1701, 1702, . . . , 170n, free layer spacers FSP1, FSP2, . . . , FSPn, and a capping layer 180. In another embodiments, there may be a spacer 140 sandwiched between the anti-pinning layer 130 and the reference layer 150. The relative position is shown in FIG. 8B and no more repeated description here. The MRAM cell forms a repeated free layer pair structure, and wherein the thickness of the relatively thin free layer 1701 is substantially the same as the thickness of the relatively thin free layer 1702.

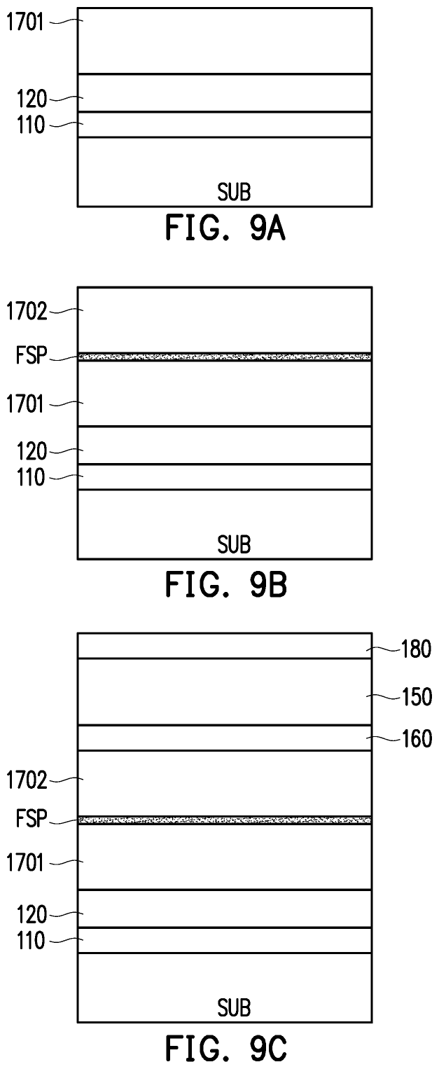

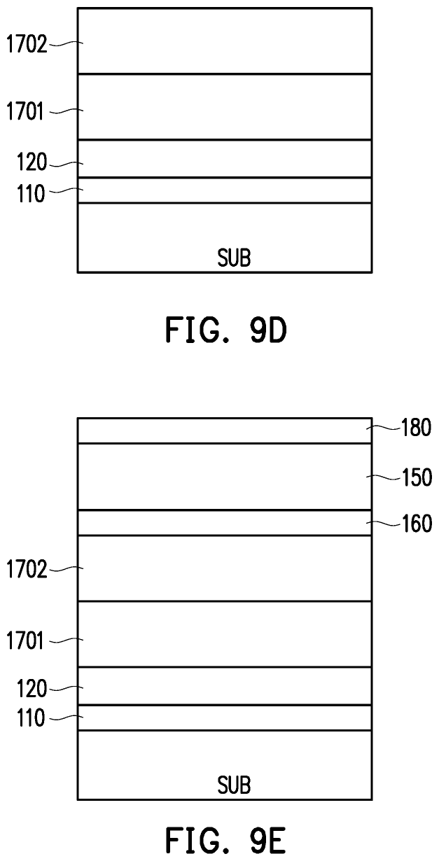

FIG. 9A through FIG. 9E are schematic cross-sectional views for illustrating a fabricating process in various stages of the MRAM cell illustrated in FIG. 4, in accordance with some exemplary embodiments of the present disclosure.

Referring to FIG. 9A to 9C, the top-down process flow for fabricating the MRAM cell is provided. In some exemplary embodiments, the MRAM cell may include a substrate SUB, a buffer layer 110, a seed layer 120, an anti-pinning layer 130, a reference layer 150, a barrier layer 160, relatively thin free layers 1701, 1702, a free layer spacer FSP, and a capping layer 180. The relative position is shown in FIG. 9C, those skilled in the art is able to easily known by referring to the embodiments mentioned above, and no more repeated description here.

Referring to FIGS. 9A to 9D and 9E, another top-down process flow for fabricating the MRAM cell is provided. In some exemplary embodiments, the MRAM cell may include a substrate SUB, a buffer layer 110, a seed layer 120, an anti-pinning layer 130, a reference layer 150, a barrier layer 160, relatively thin free layers 1701, 1702, and a capping layer 180. That is, there is no free layer spacer applied in the fabrication process, and the relatively thin free layers 1701, 1702 forms a free layer pair structure. The relative position is shown in FIG. 9E and no more repeated description here.

Referring to FIGS. 9A to 9B, 9D and 9E, in yet another embodiment, the free layer spacer FSP sandwiched between the relatively thin free layers 1701, 1702 is removed. As such, there is no free layer spacer leaved in the film stacks, and the relatively thin free layers 1701, 1702 forms a free layer pair structure.

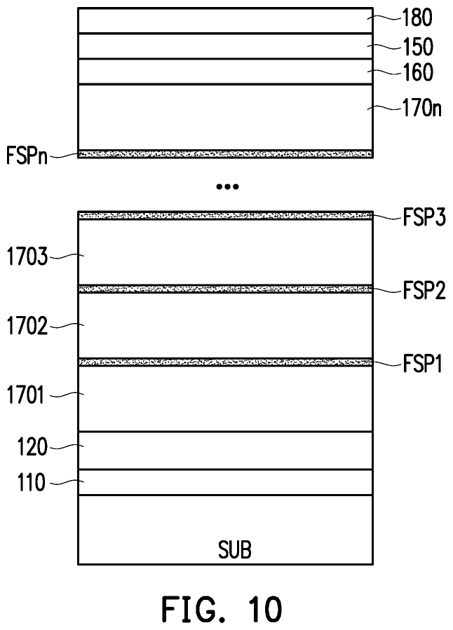

FIG. 10 is a schematic cross-sectional view of a stacked MRAM cell structure, in accordance with some embodiments. Referring to FIG. 10, the MRAM cell with multiple stacked film stack structure is provided according to a top-down process flow. In some exemplary embodiments, the MRAM cell may include a substrate SUB, a buffer layer 110, a seed layer 120, an anti-pinning layer 130, a reference layer 150, a barrier layer 160, relatively thin free layers 1701, 1702, 1703, . . . , 170n, free layer spacers FSP1, FSP2, FSP3, . . . , FSPn, and a capping layer 180. In another embodiments, there may be a spacer 140 sandwiched between the anti-pinning layer 130 and the reference layer 150. The relative position is shown in FIG. 10 and no more repeated description here. In another embodiments, the multiple stacked film stack structure provided has no free layer spacers FSP1, FSP2, FSP3, . . . , FSPn. In yet another embodiment, the free layer spacers FSP1, FSP2, FSP3, . . . , FSPn in the multiple stacked film stack structure is removed, leaving stacked free layer pair structure.

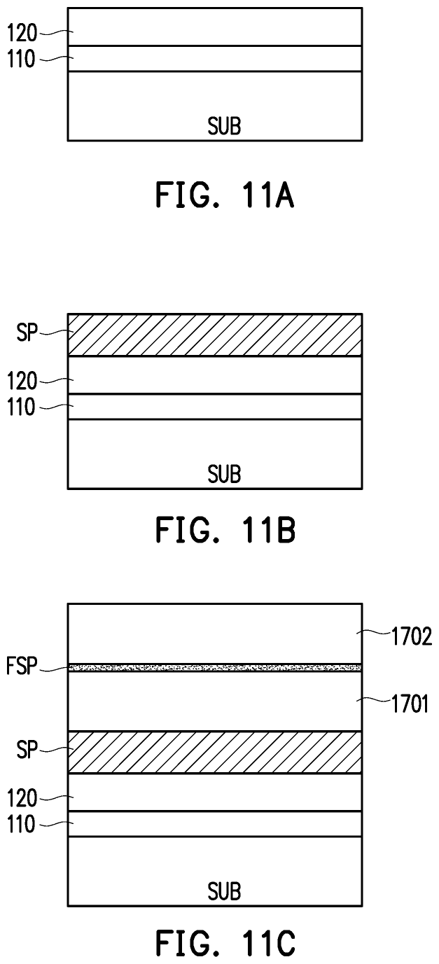

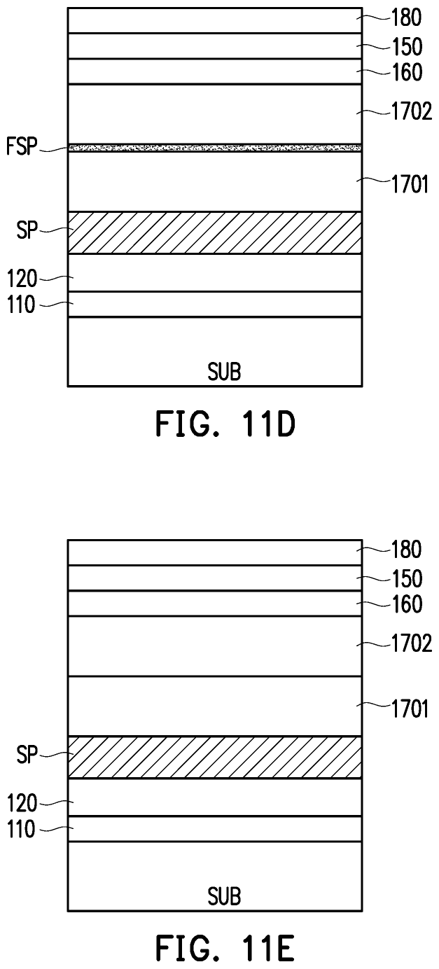

FIG. 11A through FIG. 11E are another schematic cross-sectional view for illustrating a fabricating process in various stages of the MRAM cell illustrated in FIG. 4, in accordance with some exemplary embodiments of the present disclosure.

Referring to FIG. 11A to 11D, the top-down process flow for fabricating the MRAM cell is provided. In some exemplary embodiments, the MRAM cell may include a substrate SUB, a buffer layer 110, a seed layer 120, a spacer SP, a reference layer 150, a barrier layer 160, relatively thin free layers 1701, 1702, a free layer spacer FSP, and a capping layer 180. The relative position is shown in FIG. 1 ID, those skilled in the art is able to easily known by referring to the embodiments mentioned above, and no more repeated description here.

Referring to FIG. 11A to 11E, the top-down process flow for fabricating the MRAM cell is provided. In some exemplary embodiments, the MRAM cell may include a substrate SUB, a buffer layer 110, a seed layer 120, a spacer SP, a reference layer 150, a barrier layer 160, relatively thin free layers 1701, 1702, and a capping layer 180. That is, there is no free layer spacer ESP applied in the fabrication process or the free layer spacer ESP is removed after the process illustrated in FIG. 11C. As such, the relatively thin free layers 1701, 1702 forms a free layer pair structure in FIG. 11E. The relative position is shown in FIG. 11E and no more repeated description here.

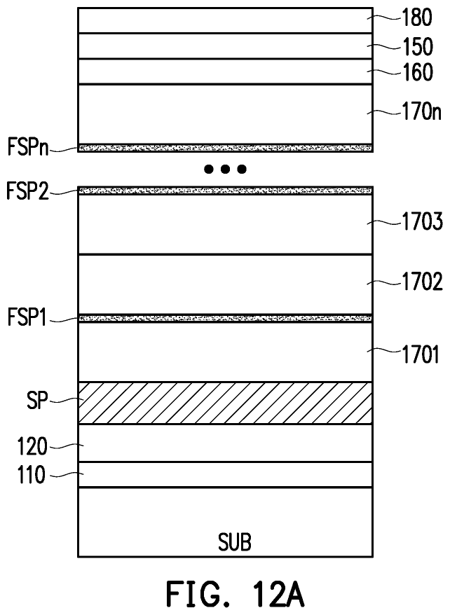

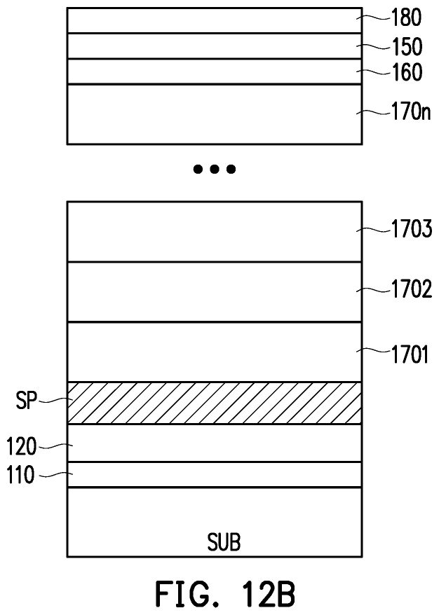

FIG. 12A and FIG. 12B are schematic cross-sectional view of different stacked MRAM cell structures, in accordance with some embodiments.

Referring to FIG. 12A and FIG. 12B, the MRAM cell with multiple stacked film stack structure is provided according to a top-down process flow. In some exemplary embodiments, the MRAM cell may include a substrate SUB, a buffer layer 110, a seed layer 120, a spacer SP, a reference layer 150, a barrier layer 160, relatively thin free layers 1701, 1702, 1703, . . . , 170n, free layer spacers FSP1, FSP2, FSP3, . . . , FSPn, and a capping layer 180. The relative position is shown in FIG. 10 and no more repeated description here. In another embodiments, the multiple stacked film stack structure provided has no free layer spacers FSP1, FSP2, FSP3, . . . , FSPn. In yet another embodiment, the free layer spacers FSP1, FSP2, FSP3, . . . , FSPn in the multiple stacked film stack structure is removed, leaving stacked free layer pair structure (e.g., 1701 and 1702).

A relatively thin free layer design is able to improve thermal retention and is able to increase exchange stiffness constant (Aₑₓ). In addition, to further reduce free layer thickness in STT-MRAM or SOT-MRAM leads to high Aₑₓ and low moment, thus improves both thermal retention and switch efficiency for high-speed and low-current memory application (e.g., cache or RAM). The stacked film stack structure design is able to further improve the efficiency factor, that is, the write current will be smaller, and the thermal retention factor will be larger.

An embodiment of the present invention relates to a memory device including a substrate, a reference layer, a tunneling layer, a film stack, and a capping layer. The reference layer is disposed on the substrate. The tunneling layer is disposed on the reference layer. The film stack formed over the tunneling layer and on the substrate, wherein the film stack comprises a first free layer, a spacer with high exchange stiffness constant and a second free layer, the first free layer is in contact with the tunneling layer and the film stack, and the spacer with high exchange stiffness constant is sandwiched between the first free layer and the second free layer. The capping layer disposed on and electrically connected to the film stack. In some embodiments, the spacer with high exchange stiffness constant is a material comprising metal elements with relatively low atomic weight selected from one of Mg, Al, Si, Ca, Cr, Co, Ta, Fe, and Ni. In some embodiments, the thickness of the spacer in the film stack is between 0.2 nm to 0.4 nm. In some embodiments, the thickness of the first free layer in the film stack is between 0.2 nm to 0.5 nm. In some embodiments, the thickness of the film stack smaller than or equal to 1 nm. In some embodiments, the spacer sandwiched between the first free layer and the second free layer is removed and then the memory device further comprises a free layer pair structure In some embodiments, the memory device forms a repeated free layer pair structure, and wherein the thickness of the first free layer is substantially the same as the thickness of the second free layer. In some embodiments, the memory device further forms a repeated structure of the film stacks and wherein the thickness of the spacer is smaller than the thickness of the first free layer. In some embodiments, the repeated number of the repeated structure of the film stacks is predetermined for adjusting the thermal retention factor. In some embodiments, the width of the first free layer is substantially larger than the width of the second free layer. In some embodiments, both the first free layer and the second free layer have a plurality of monolayers. In some embodiments, memory device further includes an auxiliary line, disposed on the capping layer; and a selector, disposed on the auxiliary line and electrically connected to a bit line and the film stack, wherein the selector is one of threshold-type selector and exponential type selector. In some embodiments, the memory device further includes a buffer layer located on top of the substrate; and a seed layer located in between the buffer layer and the reference layer. In some embodiments, the memory device further includes a buffer layer located on top of the substrate; and a seed layer located in between the buffer layer and the spacer with high exchange stiffness constant.

Another embodiment of the present invention relates to a method of fabricating a memory device. The method includes providing a plurality of transistors disposed on a substrate, forming a plurality of conductive vias electrically coupled to the plurality of transistors, forming a reference layer disposed on the substrate and electrically coupled to the plurality of conductive vias, forming a tunneling layer disposed on the reference layer, forming a film stack formed over the tunneling layer and on the substrate, forming a capping layer disposed on and electrically connected to the film stack, and forming a connecting via disposed on and electrically connected to the film stack, wherein the connecting via is partially surrounded by a shielding structure. The film stack includes a first free layer, a spacer with high exchange stiffness constant and a second free layer, the first free layer is in contact with the tunneling layer and the film stack, and the spacer with high exchange stiffness constant is sandwiched between the first free layer and the second free layer. In some embodiments, the method further includes forming the film stack comprises sequentially forming the first free layer, the spacer with high exchange stiffness constant and the second free layer, the first free layer is in contact with the tunneling layer and the film stack, and wherein the film stack are patterned together as a pillar structure standing on the tunneling layer so that sidewalls of the film stack are aligned, removing the spacer sandwiched between the first free layer and the second free layer, and providing a free layer pair structure. In some embodiments, the method further includes forming a repeated structure of a repeated free layer pair structure, wherein the thickness of the first free layer and second free layer pair structure is smaller than or equal to 1 nm. In some embodiments, the method further includes forming a repeated film stack structure, wherein the thickness of the spacer is smaller than the thickness of the first free layer.

Still another embodiment of the present invention relates to a method including the followings. A plurality of transistors disposed on a substrate is provided. A plurality of conductive vias electrically coupled to the plurality of transistors is formed. A buffer layer disposed on the substrate is formed. A seed layer disposed on the buffer layer is formed. A magnetic tunneling junction (MTJ) film stack formed over the seed layer and on the substrate is formed. The film stack comprises a first free layer, a spacer with high exchange stiffness constant and a second free layer, the first free layer is in contact with the seed layer and the film stack, and the spacer with high exchange stiffness constant is sandwiched between the first free layer and the second free layer. A tunneling layer disposed on the film stack is formed. A reference layer disposed on the tunneling layer is formed. A capping layer disposed on and electrically connected to the reference layer is formed. A connecting via disposed on and electrically connected to the film stack is formed. The connecting via is partially surrounded by a shielding structure. In some embodiments, the spacer sandwiched between the first free layer and the second free layer is removed. A first free layer and second free layer pair structure after removing the spacer is provided. A repeated film stack structure is formed. The thickness of each film stack is smaller than or equal to 1 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a substrate;
a reference layer disposed on the substrate;
a tunneling layer disposed on the reference layer;
a film stack formed over the tunneling layer and on the substrate, wherein the film stack comprises a first free layer, a spacer with high exchange stiffness constant and a second free layer, the first free layer is in contact with the tunneling layer and the film stack, and the spacer with high exchange stiffness constant is sandwiched between the first free layer and the second free layer; and
a capping layer disposed on and electrically connected to the film stack.

2. The memory device according to claim 1, wherein the spacer with high exchange stiffness constant is a material comprising metal elements with relatively low atomic weight selected from one of Mg, Al, Si, Ca, Cr, Co, Ta, Fe, and Ni.

3. The memory device according to claim 1, wherein the thickness of the spacer in the film stack is between 0.2 nm to 0.4 nm.

4. The memory device according to claim 3, wherein the thickness of the first free layer in the film stack is between 0.2 nm to 0.5 nm.

5. The memory device according to claim 4, wherein the thickness of the film stack smaller than or equal to 1 nm.

6. The memory device according to claim 1, wherein the spacer sandwiched between the first free layer and the second free layer is removed and then the memory device further comprises a free layer pair structure.

7. The memory device according to claim 6, wherein the memory device forms a repeated free layer pair structure, and wherein the thickness of the first free layer is substantially the same as the thickness of the second free layer.

8. The memory device according to claim 1, wherein the memory device further forms a repeated structure of the film stacks and wherein the thickness of the spacer is smaller than the thickness of the first free layer.

9. The memory device according to claim 8, wherein the repeated number of the repeated structure of the film stacks is predetermined for adjusting the thermal retention factor.

10. The memory device according to claim 1, wherein the width of the first free layer is substantially larger than the width of the second free layer.

11. The memory device according to claim 1, wherein both the first free layer and the second free layer have a plurality of monolayers.

12. The memory device according to claim 1, further comprises:
an auxiliary line, disposed on the capping layer; and
a selector, disposed on the auxiliary line and electrically connected to a bit line and the film stack, wherein the selector is one of threshold-type selector and exponential type selector.

13. The memory device according to claim 1, further comprising:
a buffer layer located on top of the substrate; and
a seed layer located in between the buffer layer and the reference layer.

14. The memory device according to claim 1, further comprising:
a buffer layer located on top of the substrate; and
a seed layer located in between the buffer layer and the spacer with high exchange stiffness constant.

15. A method of fabricating a memory device, comprising:
providing a plurality of transistors disposed on a substrate;
forming a plurality of conductive vias electrically coupled to the plurality of transistors;
forming a reference layer disposed on the substrate and electrically coupled to the plurality of conductive vias;
forming a tunneling layer disposed on the reference layer;
forming a film stack formed over the tunneling layer and on the substrate, wherein the film stack comprises a first free layer, a spacer with high exchange stiffness constant and a second free layer, the first free layer is in contact with the tunneling layer and the film stack, and the spacer with high exchange stiffness constant is sandwiched between the first free layer and the second free layer;
forming a capping layer disposed on and electrically connected to the film stack; and
forming a connecting via disposed on and electrically connected to the film stack, wherein the connecting via is partially surrounded by a shielding structure.

16. The method according to claim 15, further comprising:
forming the film stack comprises sequentially forming the first free layer, the spacer with high exchange stiffness constant and the second free layer, the first free layer is in contact with the tunneling layer and the film stack, and wherein the film stack is patterned together as a pillar structure standing on the tunneling layer so that sidewalls of the film stack are aligned;
removing the spacer sandwiched between the first free layer and the second free layer; and
providing a free layer pair structure.

17. The method according to claim 16, further comprising:
forming a repeated structure of a repeated free layer pair structure, wherein the thickness of the first free layer and second free layer pair structure is smaller than or equal to 1 nm.

18. The method according to claim 15, further comprising:
forming a repeated film stack structure, wherein the thickness of the spacer is smaller than the thickness of the first free layer.

19. A method of fabricating a memory device, comprising:
providing a plurality of transistors disposed on a substrate;
forming a plurality of conductive vias electrically coupled to the plurality of transistors;
forming a buffer layer disposed on the substrate;
forming a seed layer disposed on the buffer layer;
forming a film stack formed over the seed layer and on the substrate, wherein the film stack comprises a first free layer, a spacer with high exchange stiffness constant and a second free layer, the first free layer is in contact with the seed layer and the film stack, and the spacer with high exchange stiffness constant is sandwiched between the first free layer and the second free layer;
forming a tunneling layer disposed on the film stack;
forming a reference layer disposed on the tunneling layer;
forming a capping layer disposed on and electrically connected to the reference layer; and
forming a connecting via disposed on and electrically connected to the film stack, wherein the connecting via is partially surrounded by a shielding structure.

20. The method according to claim 19, further comprising:
removing the spacer sandwiched between the first free layer and the second free layer;
providing a first free layer and second free layer pair structure after removing the spacer;
forming a repeated film stack structure, wherein the thickness of each film stack is smaller than or equal to 1 nm.
